(19) United States
(12) Patent Application Publication
(10) Pub. No.: US 2007/0215927 A1
(43) Pub. Date: Sep. 20, 2007

(54) SEMICONDUCTOR DEVICE AND MANUFACTURING METHOD THEREOF

(75) Inventor: Toshiyuki Kuramochi, Nagano-shi (JP)

Correspondence Address: RANKIN, HILL, PORTER & CLARK LLP, 4080 ERIE STREET, WILLOUGHBY, OH, 44094-7836, US

(73) Assignee: SHINKO ELECTRIC INDUSTRIES CO., LTD., Nagano-shi (JP)

(21) Appl. No.: 11/686,091

(22) Filed: Mar. 14, 2007

(30) Foreign Application Priority Data
Mar. 18, 2006 (JP) 2006-075745

(51) Int. Cl. H01L 29/94

(52) U.S. Cl. 257/301

(57) ABSTRACT

In a semiconductor device in which a semiconductor element 10 in which plural electrode terminals 16 are formed along the peripheral edge inside a region of a predetermined width along the peripheral edge excluding the center and the vicinity of the center is mounted on a pad formation surface of a substrate 12 on which pads 14 corresponding to each of the electrode terminals 16 are formed and connection parts 26 between the semiconductor element 10 and the substrate 12 are sealed with an underfill material 24, it is wherein a dam 20 surrounding an inward region 28 is formed so as to separate a connection part region in which the connection parts 26 are present from the inward region 28 inward beyond the connection part region and the connection part region is sealed with the underfill material 24 and plural through holes 22 extending through the substrate 12 are formed inside the inward region 28 of the substrate 12 surrounded by the dam 20.

This application claims priority to Japanese Patent Application No. 2006-075745, filed Mar. 18, 2006, in the Japanese Patent Office. The priority application is incorporated by reference in its entirety.

### TECHNICAL FIELD

The present disclosure relates to a semiconductor device and a manufacturing method thereof. More specifically, the present disclosure relates to a semiconductor device comprising a semiconductor element, which has plural electrode terminals formed along the peripheral edge inside a region of a predetermined width along the peripheral edge excluding the center and the vicinity of the center, and a substrate, which has pads corresponding to each of the electrode terminals, wherein the semiconductor element is mounted on a pad formation surface of the substrate on which the pads are formed, and a connection part between each of the electrode terminals of the semiconductor element and the pads of the substrate is sealed with an underfill material, and a manufacturing method of the semiconductor device.

### RELATED ART

In recent years, a semiconductor device in which flip chip connection between a semiconductor element and a substrate is made has been used as a semiconductor device.

In such a semiconductor device, a gap between the semiconductor element and the substrate is filled with an underfill material and is sealed.

As such an underfill material, an underfill material made of a liquid thermosetting resin is normally used, so that there is fear that when a gap between the semiconductor element and the substrate is filled with the underfill material, the liquid underfill material flows out in the periphery and a pad formed in the vicinity of the peripheral edge of the substrate is covered.

Because of this, a manufacturing method of a semiconductor device in which a dam 104 surrounding a semiconductor element 102 mounted on the side of one surface of a substrate 100 is formed between the peripheral edge of the semiconductor element 102 and pads 108 formed in the vicinity of the peripheral edge of the substrate 100 and a distance between a side of the semiconductor element 102 and the dam 104 of a place for dropping a liquid underfill material 106 is made longer than a distance between another side of the semiconductor element 102 and a dam 104 as shown in FIGS. 6A and 6B has been proposed in Patent Reference 1 (Japanese Patent Unexamined Publication No. 2005-276879).

According to the manufacturing method of the semiconductor device proposed in Patent Reference 1 carried above, the fear that when a gap between the semiconductor element 102 and the substrate 100 is filled with the liquid underfill material 106, the underfill material 106 flows out in the periphery and the pads 108 formed in the vicinity of the peripheral edge of the substrate 100 are covered can be solved.

However, a semiconductor element 102 in which plural electrode terminals 110, 110 . . . are formed along the peripheral edge inside a region of a predetermined width along the peripheral edge excluding the center as shown in FIG. 7 is generally used as the semiconductor element 102. When such a semiconductor element 102 shown in FIG. 6A is mounted on the side of one surface of the substrate 100 and a gap between the semiconductor element 102 and the substrate 100 is filled with the liquid underfill material 106, it proved that bubbles 200, 200 . . . tend to remain in the portion and the vicinity of the underfill material 106 for sealing the electrode terminals 110, 110 . . . as shown in FIG. 7.

### SUMMARY

Embodiments of the present invention provide a semiconductor device in which bubbles can resist remaining in an underfill material for sealing a connection part and the vicinity of the connection part, the connection part being formed by flip chip connection between the side of one surface of a substrate and a semiconductor element having plural electrode terminals formed along the peripheral edge inside a region of a predetermined width along the peripheral edge excluding the center, and a manufacturing method of the semiconductor device.

As a result of examination in order to solve the problem, the present inventor found that bubbles resist remaining in an underfill material for sealing a connection part between electrode terminals of a semiconductor element and pads of a substrate and the vicinity of the connection part by forming a dam surrounding an inward region so as to separate a connection part region in which the connection part between each of the electrode terminals of the semiconductor element and the pads of the substrate is present from the inward region inward beyond this connection part region, and reached the invention.

That is, one or more embodiments of the invention provide a semiconductor device comprising a semiconductor element, which has plural electrode terminals formed along the peripheral edge inside a region of a predetermined width along the peripheral edge excluding the center and the vicinity of the center, and a substrate, which has pads corresponding to each of the electrode terminals. In the semiconductor device, the semiconductor element is mounted on a pad formation surface of the substrate on which the pads are formed, and a connection part between each of the electrode terminals of the semiconductor element and the pads of the substrate is sealed with an underfill material. Further, in the semiconductor device, a dam surrounding an inward region is formed so as to separate a connection part region, in which the connection part between each of the electrode terminals of the semiconductor element and the pads of the substrate is present, from the inward region, which is inward beyond the connection part region. Furthermore, in the semiconductor device, the connection part region is sealed with an underfill material made of a thermosetting resin and plural through holes extending through the substrate are formed inside the inward region of the substrate surrounded by the dam.

Also, one or more embodiments of the invention provide a manufacturing method of a semiconductor device in which a semiconductor element having plural electrode terminals formed along the peripheral edge inside a region of a predetermined width along the peripheral edge excluding the center is mounted on a pad formation surface of a substrate on which pads corresponding to each of the electrode terminals are formed, and a connection part between each of the electrode terminals of the semiconductor element and the pads of the substrate is sealed with an underfill material. The manufacturing method comprises a step of separating a connection part region, in which the connection part between each of the electrode terminals of the semiconductor element and the pads of the substrate is present, from an inward region inward beyond the connection part region by a dam surrounding the inward region while mounting the semiconductor element on the side of one surface of the substrate in which plural through holes are formed in the portion corresponding to the inward region, a step of filing a gap between the semiconductor element and the substrate with an underfill material made of a liquid thermosetting resin from the outside of the peripheral edge of the semiconductor element, and thereafter hardening the underfill material.

In one or more embodiments of the invention, the connection part between the substrate and the semiconductor element of the semiconductor device obtained by mounting the semiconductor element on the substrate by flip chip connection can be effectively filled with the underfill material.

Further, the dam surrounding the inward region is formed on an electrode terminal formation surface of the semiconductor element in which the electrode terminals are formed or the pad formation surface of the substrate in which the pads are formed so as to separate the electrode terminal region of the semiconductor element or the pad formation region of the substrate from the inward region inward beyond the electrode terminal region or the pad formation region. Therefore, the connection part region in which the connection part between each of the electrode terminals of the semiconductor element and the pads of the substrate is present can be easily separated from the inward region inward beyond this connection part region by mounting the semiconductor element on the side of one surface of the substrate.

Also, by forming the inward region of the substrate in a space part, weight of the semiconductor device can be reduced and an underfill material can be saved.

On the other hand, by sealing the inward region of the substrate by injecting the underfill material of different kinds or the same kind as the underfill material with which the electrode terminal region is sealed through the through holes formed in the inward region of the substrate, when pressure force is applied to the semiconductor device, damage to the semiconductor element can be prevented and humidity resistance and heat resistance can be improved.

When a gap between a substrate and a semiconductor element of a semiconductor device is filled with an underfill material, a liquid underfill material 106 is supplied to the outside of the peripheral edge of a semiconductor element 102 while moving one nozzle 112 as shown in FIG. 8A or two nozzles 112, 112 as shown in FIG. 8B. The gap between the substrate 100 and the semiconductor element 102 is filled with the supplied liquid underfill material 106 while the underfill material 106 spreads by a capillary phenomenon.

However, when connection parts between each of the electrode terminals 110 of the semiconductor element 102 and pads of the substrate 100 are present inside a region of a predetermined width along the peripheral edge of the semiconductor element 102 excluding the center and the vicinity of the center, places of circle marks shown in FIGS. 8A and 8B protrude partially and a recessed part is formed in the connection parts between the electrode terminals 110 and the pads of the substrate 100 and the vicinity of the connection parts (between the circle marks of FIGS. 8A and 8B). Air is inhaled in such a recessed part and bubbles tend to remain.

In this respect, in the one or more embodiments of the invention, a connection part region in which a connection part between each of the electrode terminals of a semiconductor element and pads of a substrate is present is separated from an inward region inward beyond this connection part region by a dam surrounding the inward region. As a result of this, when a gap between the semiconductor element and the substrate is filled with an underfill material made of a liquid thermosetting resin from the outside of the peripheral edge of the semiconductor element, the inside of the narrow connection part region separated from the inward region by the dam is uniformly filled with the underfill material and occurrence of bubbles caused by nonuniformity of spreading of the underfill material can be prevented.

Further, in the one or more embodiments of the invention, plural through holes are formed in the portion corresponding to an inward region of a substrate, so that when an underfill material made of a thermosetting resin with which a gap between a semiconductor element and the substrate is filled is hardened under the heated atmosphere, air in the inward region can be vented and damage to the semiconductor element can be prevented.

As a result of that, according to a semiconductor device obtained by a manufacturing method of a semiconductor device according to the one or more embodiments of the invention, stable humidity resistance and heat resistance can be achieved.

Other features and advantages maybe apparent from the following detailed description, the accompanying drawings and the claims.

### BRIEF DESCRIPTION OF THE DRAWINGS

FIG. 1 is a longitudinal sectional view describing one example of a semiconductor device according to the invention.

FIG. 2 is a transverse sectional view of the semiconductor device shown in FIG. 1.

FIG. 3 is a longitudinal sectional view describing another example of a semiconductor device according to the invention.

FIG. 4 is a longitudinal sectional view describing a further example of a semiconductor device according to the invention.

FIG. 5 is a longitudinal sectional view describing a further example of a semiconductor device according to the invention.

FIG. 6A and 6B are longitudinal sectional views describing a related-art semiconductor device.

FIG. 7 is a transverse sectional view describing bubbles remaining in an underfill material of the semiconductor device shown in FIG. 6A.

FIGS. 8A and 8B are explanatory diagrams describing a situation of a liquid underfill material with which a gap between a substrate and a semiconductor element is filled.

### DETAILED DESCRIPTION

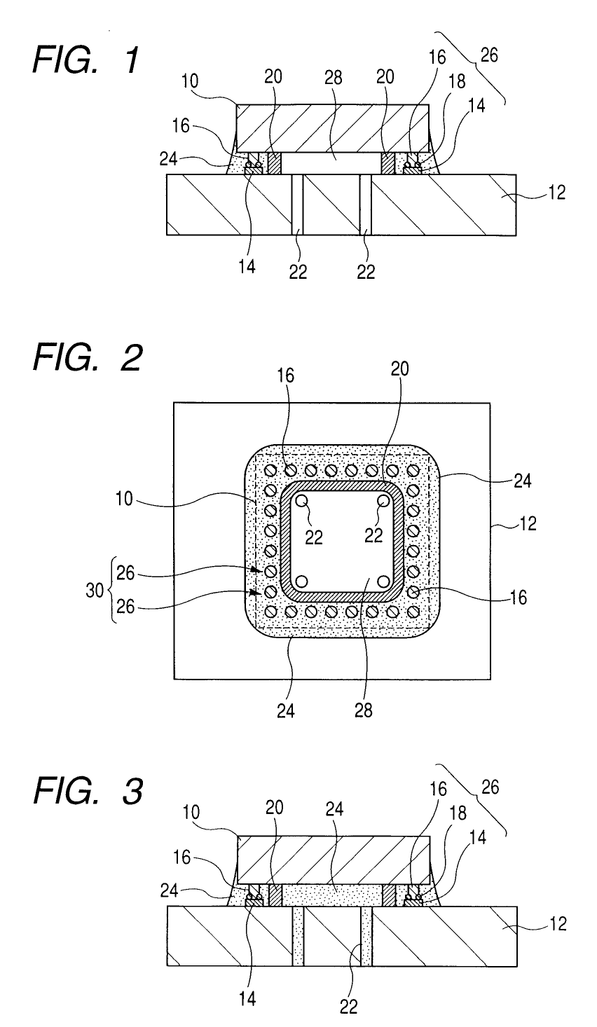

One example of a semiconductor device according to the invention is shown in FIG. 1. The semiconductor device shown in FIG. 1 is formed by mounting a semiconductor element 10, in which plural electrode terminals 16, 16 . . . are formed along the peripheral edge inside a region of a predetermined width along the peripheral edge excluding the center and the vicinity of the center, on a pad formation surface of a substrate, on which pads 14 corresponding to each of the electrode terminals 16, 16 . . . are formed. The pad formation surface of this substrate 12 is larger than an electrode terminal formation surface of the semiconductor element 10. Such electrode terminal 16 and pad 14 form a connection part 26 secured by solder 18. The connection part 26 between this electrode terminal 16 and the pad 14 is sealed with an underfill material 24. As such an underfill material 24, a thermosetting resin is normally used.

Also, in the semiconductor device shown in FIG. 1, a connection part region 30 in which the connection parts 26 between each of the electrode terminals 16, 16 . . . of the semiconductor element 10 and the pads 14 of the substrate 12 are present is separated from an inward region 28 inward beyond this connection part region 30 by a dam 20 surrounding the inward region 28 as shown in FIG. 2. The electrode terminal 16 or the pad 14 is not formed in such an inward region 28 and a space part is formed in the inward region 28.

Plural through holes 22, 22 . . . are formed in the portion of the substrate 12 corresponding to this inward region 28. Such through holes 22, 22 . . . serve as vent holes for supplying and discharging air in the space part when the semiconductor device shown in FIG. 1 is subjected to a wet heat test.

When the through holes 22, 22 . . . are not formed herein, there is fear that when the semiconductor device shown in FIG. 1 is subjected to the wet heat test, a pressure of the space part increases and the semiconductor element 10 is broken.

In the case of manufacturing such a semiconductor device shown in FIG. 1, the dam 20 surrounding the inward region 28 is formed on the pad formation surface of the substrate 12 on which the pads 14 corresponding to each of the electrode terminals 16, 16 . . . of the semiconductor element 10 are formed so as to separate a pad formation region of the substrate 12 on which the pads 14, 14 . . . are formed from the inward region 28 inward beyond this pad formation region.

In such a dam 20, a solder resist layer with a predetermined thickness made of a photosensitive solder resist is formed on one surface of the pad formation surface of the substrate 12 and thereafter the solder resist layer is patterned by light exposure and development and the dam 20 with a predetermined height and a predetermined shape can be formed.

Then, flip chip connection between the semiconductor element 10 and the pad formation surface of the substrate 12 is made. In this case, the semiconductor element 10 is abutted on the pads 14 to which each of the electrode terminals 16, 16 . . . corresponds and thereafter the connection parts 26 are formed by fixing the electrode terminals 16 to the pads 14 by the solder 18.

By such flip chip connection, the connection part region 30 in which the connection parts 26 between each of the electrode terminals 16, 16 . . . of the semiconductor element 10 and the pads 14 of the substrate 12 are present is separated from the inward region 28 inward beyond this connection part region 30 by the dam 20 surrounding the inward region 28.

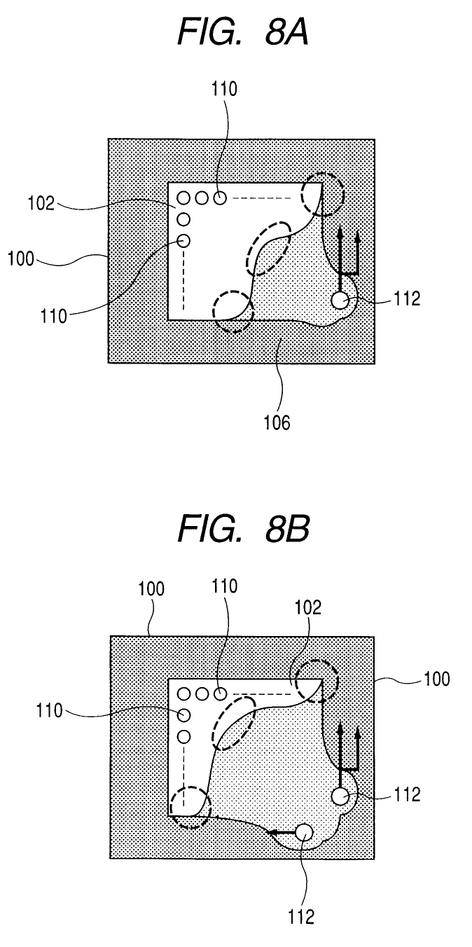

Then, a gap between the semiconductor element 10 and the substrate 12 is filled with the underfill material 24 made of a liquid thermosetting resin from the outside of the peripheral edge of the semiconductor element 10. In this case, as shown in FIG. 8A, the underfill material 24 is supplied from a nozzle 112 to the outside of the peripheral edge of the semiconductor element 10, and it is preferable to supply the underfill material 24 in two places different in a stationary state in the nozzle 112. It is particularly preferable to supply the underfill material 24 from the nozzle 112 in a stationary state in the vicinity of one corner of the rectangular semiconductor element 10 and then supply the underfill material 24 from the nozzle 112 moved in the vicinity of the other corner located in a position opposite to one corner.

In this manner, the underfill material 24 made of the liquid thermosetting resin supplied from the outside of the semiconductor element 10 spreads the inside of the connection part region 30 at substantially uniform speed by a capillary phenomenon without leaching into the inward region 28 surrounded by the dam 20. As a result of this, bubbles do not remain in the connection parts 26 or its vicinity and the connection parts 26, 26 . . . are sealed with the underfill material 24. On the other hand, the inward region 28 surrounded by the dam 20 is formed in the space part.

Then, after a gap in the substrate 12 is filled with the liquid underfill material 24, the semiconductor element 10, the substrate 12 and the underfill material 24 are inserted into the heated atmosphere and hardening is completed. In this case, air of the inward region 28 which is surrounded by the dam 20 and is the space part is discharged from the through holes 22, 22 . . . formed in the substrate 12 of the inward region 28. As a result of this, a situation in which an inner pressure of the inward region 28 increases and the semiconductor element 10 is broken can be prevented.

In the semiconductor device obtained in this manner, the connection parts 26 between each of the electrode terminals 16, 16 . . . of the semiconductor element 10 and the pads 14 of the substrate 12 and the vicinity of the connection parts 26 are sufficiently sealed with the underfill material 24. As a result of this, characteristics of humidity resistance, heat resistance, etc. of such a semiconductor device can be improved and reliability of the semiconductor device can be improved.

In the semiconductor device shown in FIGS. 1 and 2, the inward region 28 surrounded by the dam 20 is formed in the space part, but the inward region 28 may be filled with the underfill material 24 by injecting the liquid underfill material 24 from the through holes 22, 22 . . . formed in the substrate 12 as shown in FIG. 3. This filling may be performed after the connection part region 30 is filled with the underfill material 24 or before the connection part region 30 is filled with the underfill material 24.

Also, underfill materials of different kinds or the same kind as the underfill material 24 with which the connection part region 30 is filled can be used as the underfill material 24 with which the inward region 28 is filled.

By filling the inward region 28 with the underfill material 24 in this manner, when pressure force is applied tot he semiconductor device, damage to the semiconductor element 10 can be prevented and humidity resistance and heat resistance can be improved.

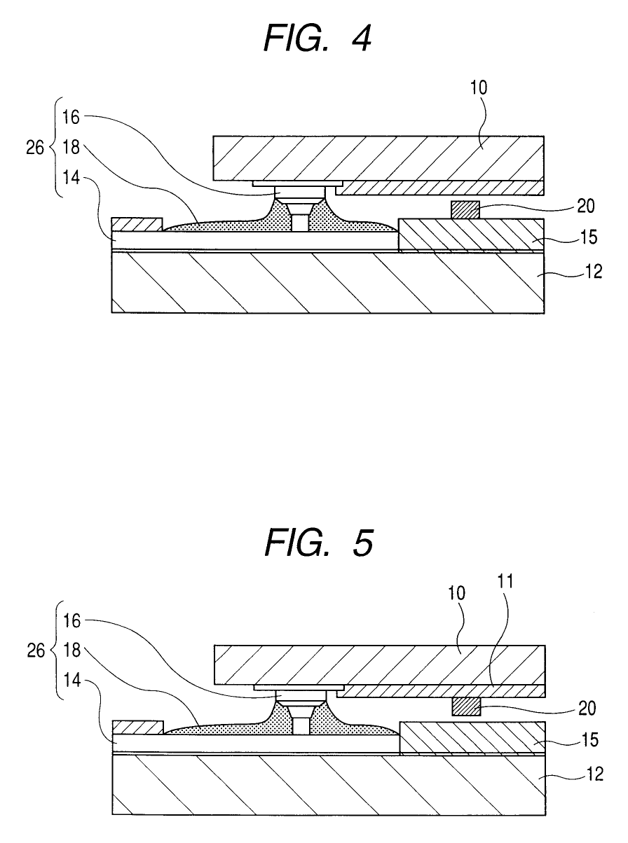

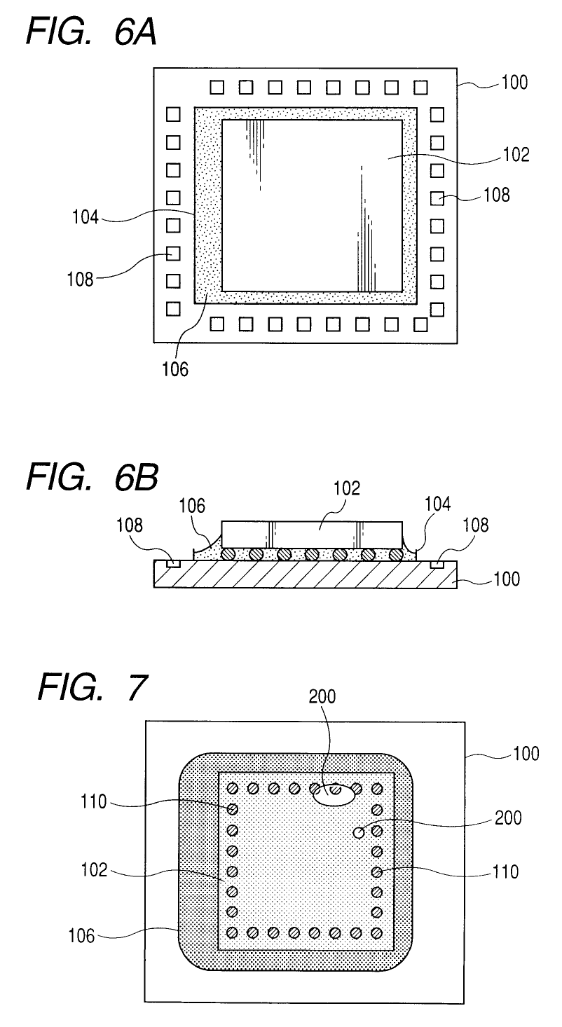

In the semiconductor device shown in FIGS. 1 to 3, both end surfaces of the dam 20 make close contact with the electrode terminal formation surface of the semiconductor element 10 and the pad formation surface of the substrate 12, but when the underfill material 24 containing a filler is used as the underfill material 24, a gap may be formed between a dam 20 and an electrode terminal formation surface of a semiconductor element 10 or a pad formation surface of a substrate 12 as shown in FIGS. 4 and 5. This gap is preferably a gap of about particle size distribution of the filler contained in the underfill material 24, concretely, about 5 to 0.5 μm.

Here, the dam 20 shown in FIG. 4 is formed on a solder resist layer 15 with which the pad formation surface of the substrate 12 is covered. Also, the dam 20 shown in FIG. 5 is formed on a passivation film 11 of the electrode terminal formation surface of the semiconductor element 10.

Further, in the semiconductor device shown in FIGS. 1 to 5, the semiconductor device in which the substrate 12 is wider (larger) than the semiconductor element 10 has been described, but the invention can also be applied to a CSP in which the substrate 12 is substantially the same width (size) as the semiconductor element 10.

What is claimed is:

1. A semiconductor device comprising:
a semiconductor element which has plural electrode terminals formed along a peripheral edge inside a region of a predetermined width along the peripheral edge excluding the center;
a substrate which has pads corresponding to each of the electrode terminals, the substrate having a pad formation surface on which the pads are formed and the semiconductor element is mounted;
a dam which surrounds an inward region and separates a connection part region from the inward region, the connection part region having a connection part between each of the electrode terminals of the semiconductor element and the pads of the substrate, the inward region being inward beyond the connection part region; and
an underfill material which seals the connection part region and is made of a thermosetting resin.

2. A semiconductor device as claimed in claim 1, wherein flip chip connection between the semiconductor element and the substrate is made.

3. A semiconductor device as claimed in claim 1, wherein the dam protrudes from an electrode formation surface of the semiconductor element in which the electrode terminals are formed or the pad formation surface of the substrate.

4. A semiconductor device as claimed in claim 1, wherein the inward region is formed in a space part.

5. A semiconductor device as claimed in claim 1, wherein the inward region is sealed with an underfill material of different kinds or the same kind as the underfill material with which the connection part region is sealed.

6. A semiconductor device as claimed in claim 1, wherein plural through holes extending through the substrate are formed inside the inward region of the substrate surrounded by the dam.

7. A manufacturing method of a semiconductor device in which a semiconductor element having plural electrode terminals formed along a peripheral edge inside a region of a predetermined width along the peripheral edge excluding the center is mounted on a pad formation surface of a substrate on which pads corresponding to each of the electrode terminals are formed, the method comprising:
separating a connection part region, which has a connection part between each of the electrode terminals of the semiconductor element and the pads of the substrate, from an inward region, which is inward beyond the connection part region, by a dam surrounding the inward region while mounting the semiconductor element on the pad formation surface of the substrate;
filling a gap between the semiconductor element and the substrate with an underfill material made of a liquid thermosetting resin from the outside of the peripheral edge of the semiconductor element; and
hardening the underfill material.

8. A manufacturing method of a semiconductor device as claimed in claim 7, further comprising:
performing flip chip connection between the semiconductor element and the substrate.

9. A manufacturing method of a semiconductor device as claimed in claim 7, further comprising:
forming the dam surrounding the inward region on an electrode terminal formation surface of the semiconductor element in which the electrode terminals are formed or the pad formation surface of the substrate in which the pads are formed so as to separate the electrode terminal region of the semiconductor element or the pad formation region of the substrate from the inward region inward beyond the electrode terminal region or the pad formation region.

10. A manufacturing method of a semiconductor device as claimed in claim 7, wherein the inward region is formed in a space part.

11. A manufacturing method of a semiconductor device as claimed in claim 7, wherein the inward region is sealed by injecting a liquid underfill material of different kinds or the same kind as the underfill material with which the connection part region is sealed through through holes formed in the inward region of the substrate.
